(19) United States
(12) Patent Application Publication
(10) Pub. No.: US 2008/0228301 A1
(43) Pub. Date: Sep. 18, 2008

(54) SYSTEM TO OPTIMIZE A SEMICONDUCTOR PROBE CARD

(75) Inventor: Cameron Dennis, Austin, TX (US)

Correspondence Address: MANUEL F. DE LA CERRA, 6885 CATAMARAN DRIVE, CARLSBAD, CA, 92011, US

(73) Assignee: TOUCHDOWN TECHNOLOGIES, INC., Baldwin Park, CA (US)

(21) Appl. No.: 11/686,768

(22) Filed: Mar. 15, 2007

(51) Int. Cl. G06F 11/00

(52) U.S. Cl. 700/97

(57) ABSTRACT

A novel information system for optimizing a phase in the lifespan of a probe card for semiconductor wafer testing, by receiving, storing, and disseminating probe card data over a network between the probe card customer and supplier. The system optimizes the ordering of a probe card by a customer, the manufacture of the probe card by a supplier, and the performance and repair of the probe card during its lifespan. The information system includes at least one server that is coupled to a network, where the server receives, stores, and disseminates historical information gathered during the order, manufacture, performance, and repair phases of many probe cards. An application on the server receives current information from a probe card customer or supplier, calculates a variety of metrics based on this information, compares the metric to historical data already stored in the system, and communicates the results of the comparison and the historical data to a system user.

Other advantageous features include probe cards equipped with attached data storage devices, such as radio frequency identification (RFID) tags, allowing the customer and supplier to store and easily access current order, manufacture, performance, and repair information on a particular probe card. The system may also automatically receive current information, calculate metrics, compare the metrics to historical data, and communicate the results of the comparison and the historical data to the customer or supplier using the system.

### FIELD OF THE INVENTION

The present invention relates to testing semiconductor wafers and more particularly to a system for optimizing the structure, performance and manufacture of probe cards for semiconductor wafer testing.

### BACKGROUND OF THE INVENTION

Integrated circuits are made in a bulk parallel process by patterning and processing semiconductor wafers. Each wafer contains many identical copies of the same integrated circuit referred to as a “die.” Semiconductor wafers must be tested before the die is cut into individual integrated circuits and packaged for sale. If defects are detected the defective die can be culled before wasting resources packaging a defective part.

To test a wafer, a probe card is commonly used which comes into contact with the surface of the wafer. The probe card generally contains three unique characteristics: (1) an XY array of individual probes that bend in the Z direction to allow contact with the die; (2) an electrical interface to connect the card to a circuit test apparatus; and (3) a rigid reference plane defined in such a way that the probe card can be accurately mounted in the same location on the wafer tester. FIG. 8 illustrates an array of generic probes (A) on a substrate (B). Probe tips (C) for each probe in the array (A) are allowed to bend in the Z direction (perpendicular to the substrate (B)). When the probe card is brought in contact with the die, the Z-direction bending allows for a solid contact with the probe tip (C). The probe card ultimately provides an electrical interface that allows a circuit test apparatus to be temporarily connected to the individual die, this event is called a touchdown.

This method of die testing is extremely efficient because many die can be tested at the same time. To drive this efficiency even higher, probe card manufacturers are making larger probe cards with an ever-increasing numbers of probes. Current state of the art semiconductor manufacturing routinely produces contact pad sizes of 80 um with inter-pad spacing on a 100 um pitch. A current probe card may have as many as 5,000 or more individual probes that must accurately engage the contact pads. The XYZ positional accuracy required for each of the individual probes is on the order of ±15 um in all directions. Also, manufacturers use the probe cards to test thousands of die, requiring the probe card to perform thousands of touchdowns.

The typical probe card manufacturing process is shown in FIG. 9. Beginning at step 1105 the customer places an order with the probe card supplier. The order generally contains information as to the particular layout of the probe card, contacts and the number of probes needed on the card. At step 1110, the probe supplier contacts the customer regarding the probe design. At this point it may be possible at step 1115 for the probe card customer to use a web-based system to design the probe card. One such system is disclosed in U.S. Pat. No. 6,714,828 entitled “Method and System for Designing a Probe Card.” Through this process, the probe card customer achieves a design that will meet its particular needs. The probe card supplier transmits the final order to the customer so that the customer can confirm the order at step 1120. If the probe card supplier has any changes to the design of the probe card, the probe card design can be restarted at step 1108. Once the final order has been approved by the customer, the probe card supplier can specify quantity and delivery time at step 1125. The probe card manufacturing begins at step 1130. Generally at this point the probe card customer performs a cursory review of the probe card upon delivery, and if it accepts the probe card it is placed into use at step 1135. The customer continues to use a card until it is retired, at which time the customer may restart the process and order another probe card from the probe card supplier. Should the customer instead reject the probe card at step 1140 then the supplier attempts to repair the probe card to return it back to the customer.

Throughout the process just described with regards to FIG. 11, both the supplier and customer generate valuable information regarding the probe card structure, performance, and manufacture. Unfortunately however, this information is not centrally located or even shared between the supplier and customer.

What is needed therefore, is a system that coordinates, receives, stores and disseminates information from both supplier and customer. Moreover, the system can use the information to optimize the structure, performance and manufacture of the probe card.

### SUMMARY OF THE INVENTION

The present specification discloses a novel information system for optimizing a phase in the lifespan of a probe card for semiconductor wafer testing, by receiving, storing, and disseminating probe card data over a network between the probe card customer and supplier. The system optimizes the ordering of a probe card by a customer, the manufacture of the probe card by a supplier, and the performance and repair of the probe card during its lifespan. The information system includes at least one server that is coupled to a network, where the server receives, stores, and disseminates historical information gathered during the order, manufacture, performance, and repair phases of many probe cards. Specifically, an application on the server receives current information from a probe card customer or supplier, calculates a variety of metrics based on this information, compares the metric to historical data already stored in the system, and communicates the results of the comparison and the historical data to a system user. The customized communication of metric and historical information during the order, manufacture, performance, and repair phases of a probe card allow the probe card customer and supplier to save time, costs, and manufacturing resources. It may also be advantageous for the customer and supplier to have access to and use the current information, metrics calculations, and historical data stored on the other's server.

The system includes other advantageous features, including probe cards equipped with attached data storage devices, such as radio frequency identification (RFID) tags, allowing the customer and supplier to store and easily access current order, manufacture, performance, and repair information on a particular probe card. The information system may also be automated, such that it automatically receives current information, calculates metrics, compares the metrics to historical data, and communicates the results of the comparison and the historical data to the customer or supplier using the system.

### BRIEF DESCRIPTION OF THE DRAWINGS

FIG. 1A illustrates the upload of probe card data during the probe card's lifespan in accordance with the novel probe card information system.

FIG. 1B illustrates the download of probe card data during the probe card's lifespan in accordance with the novel information system.

FIG. 2A illustrates the upload of order data during the order phase of the probe card's lifespan in accordance with the novel information system.

FIG. 2B illustrates the download of order data during the order phase of the probe card's lifespan in accordance with the novel information system.

FIG. 3A illustrates the upload of manufacturing data during the manufacture phase of the probe card's lifespan in accordance with the novel information system.

FIG. 3B illustrates the download of manufacturing data during the manufacture phase of the probe card's lifespan in accordance with the novel information system.

FIG. 4 illustrates the upload of performance data during the performance phase of the probe card's lifespan in accordance with the novel information system.

FIG. 5A illustrates the upload of repair data during the repair phase of the probe card's lifespan in accordance with the novel information system.

FIG. 5B illustrates the download of repair data during the repair phase of the probe card's lifespan in accordance with the novel information system.

FIG. 6 is an illustration of a web-based system whereby probe card information is shared over a network between the supplier and customer in accordance with the novel information system.

FIG. 7 illustrates the process by which the customer or supplier can store or retrieve information from a web-based processing center in accordance with the novel information system.

FIG. 8 is an illustration of an array of probes on a probe card substrate.

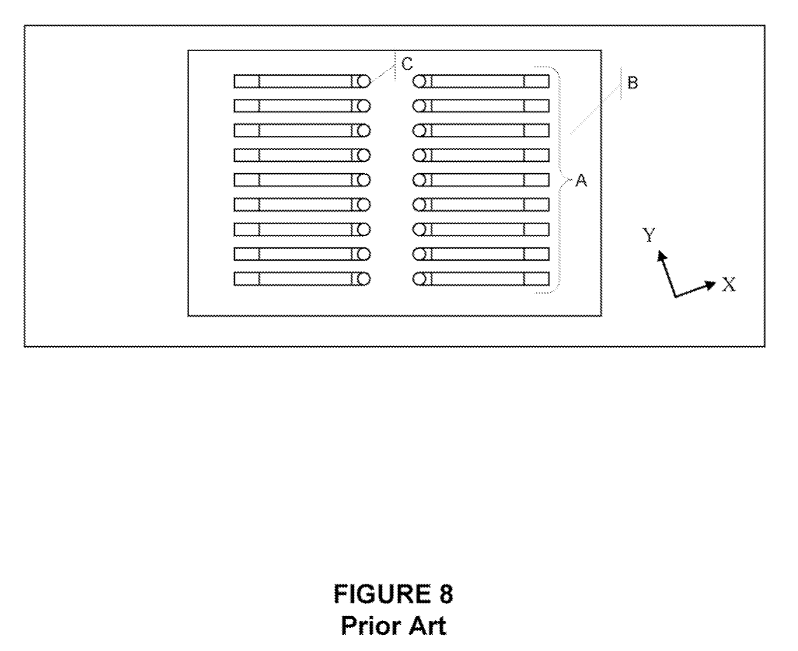

FIG. 9 illustrates the typical probe card manufacturing process without the novel probe card information system.

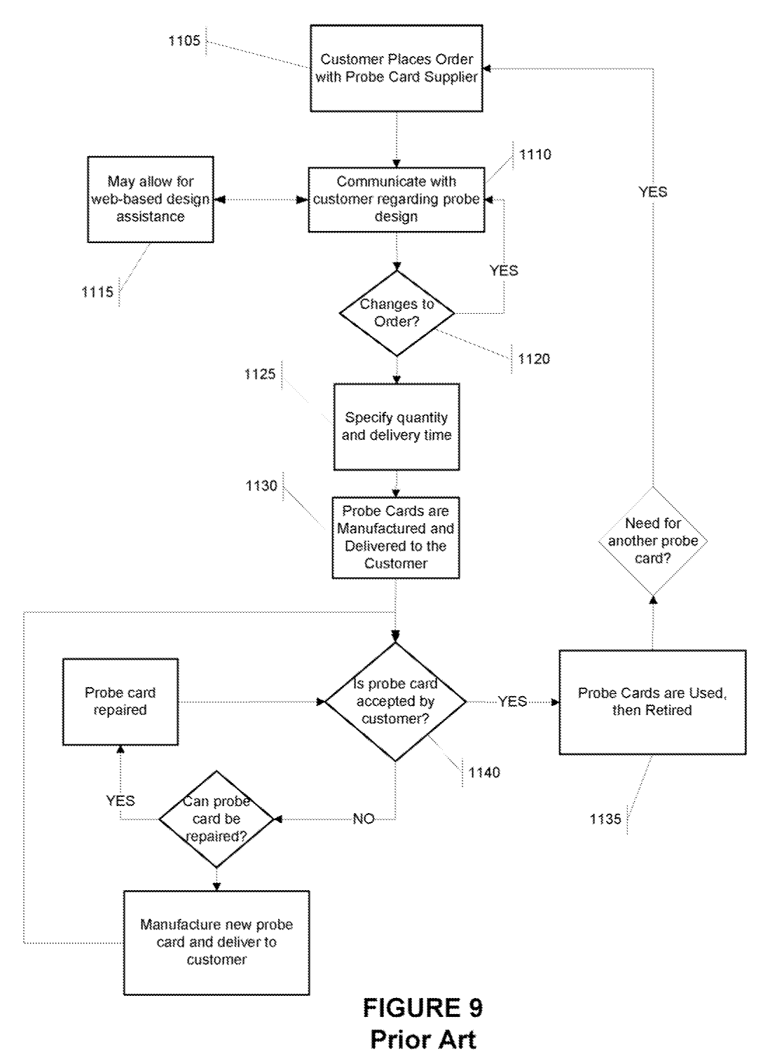

### DETAILED DESCRIPTION

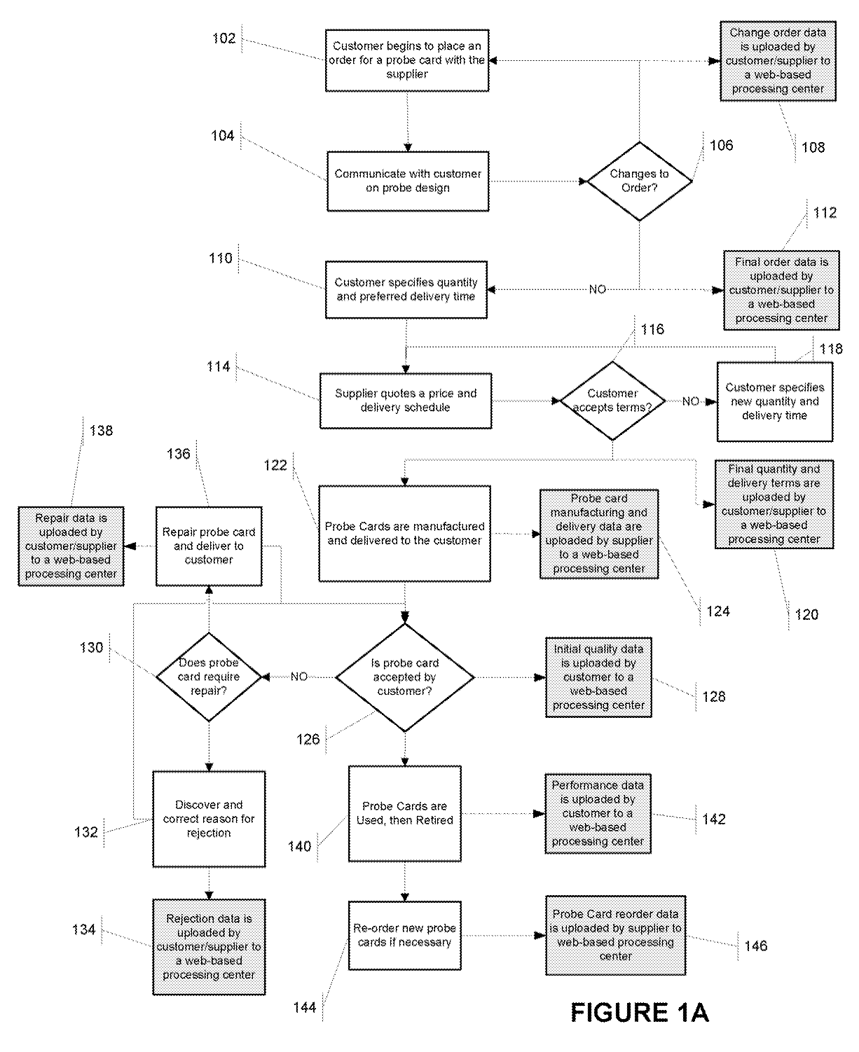

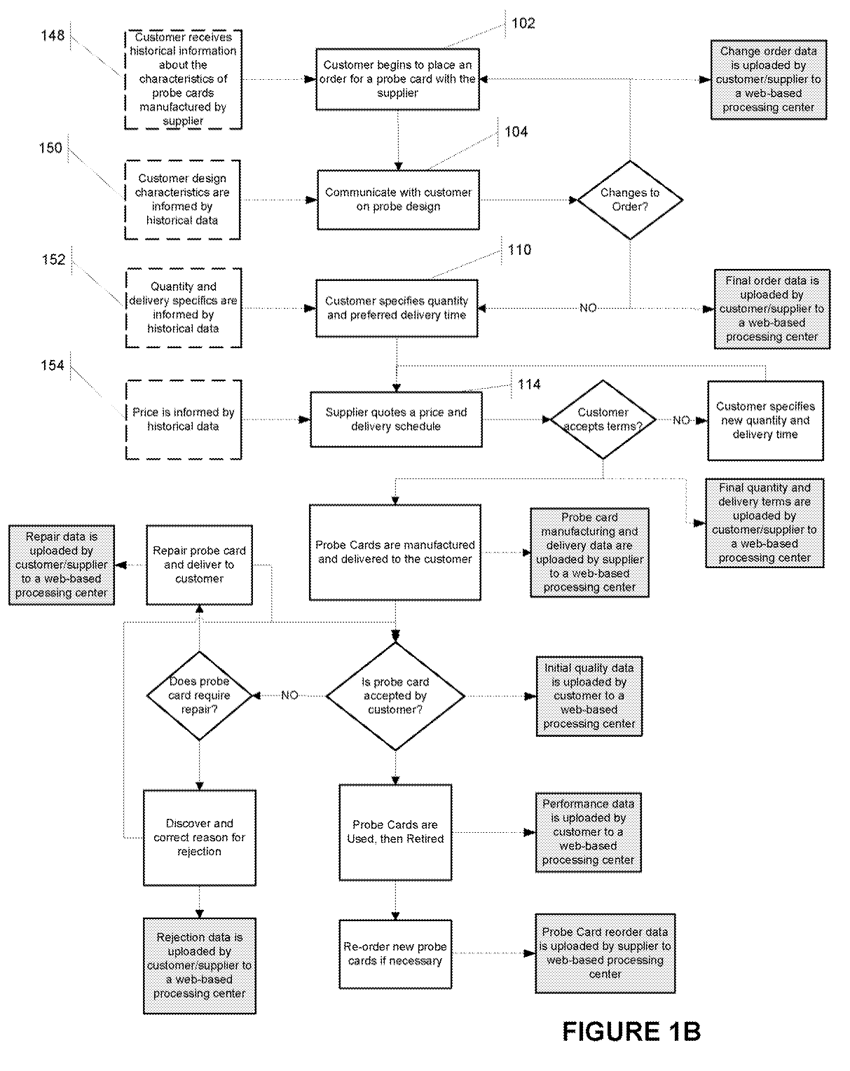

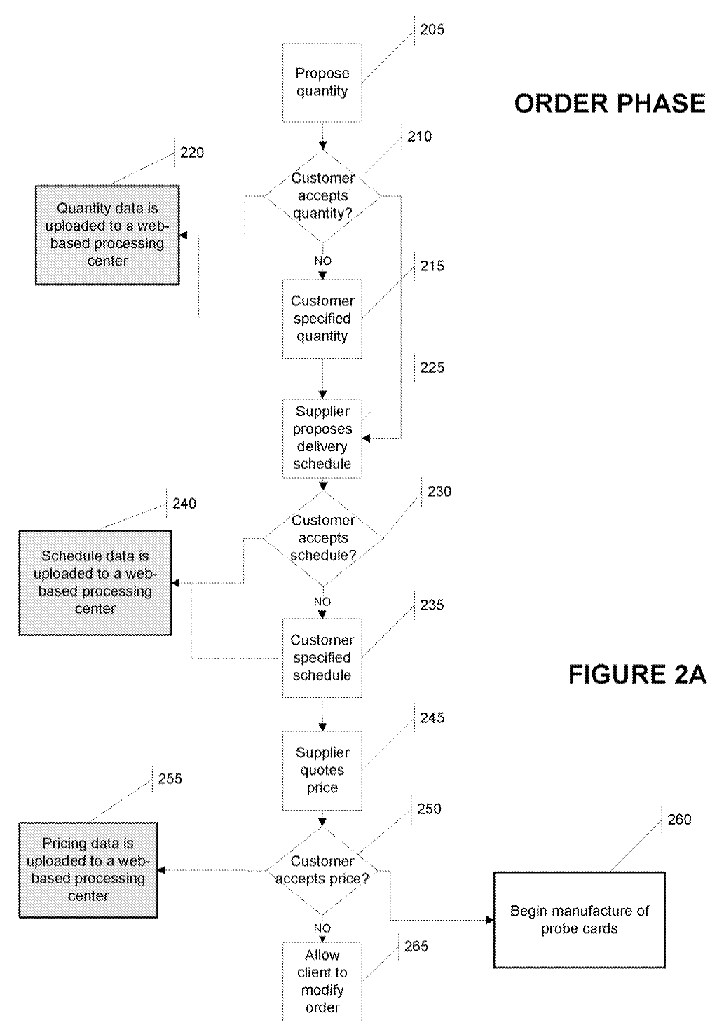

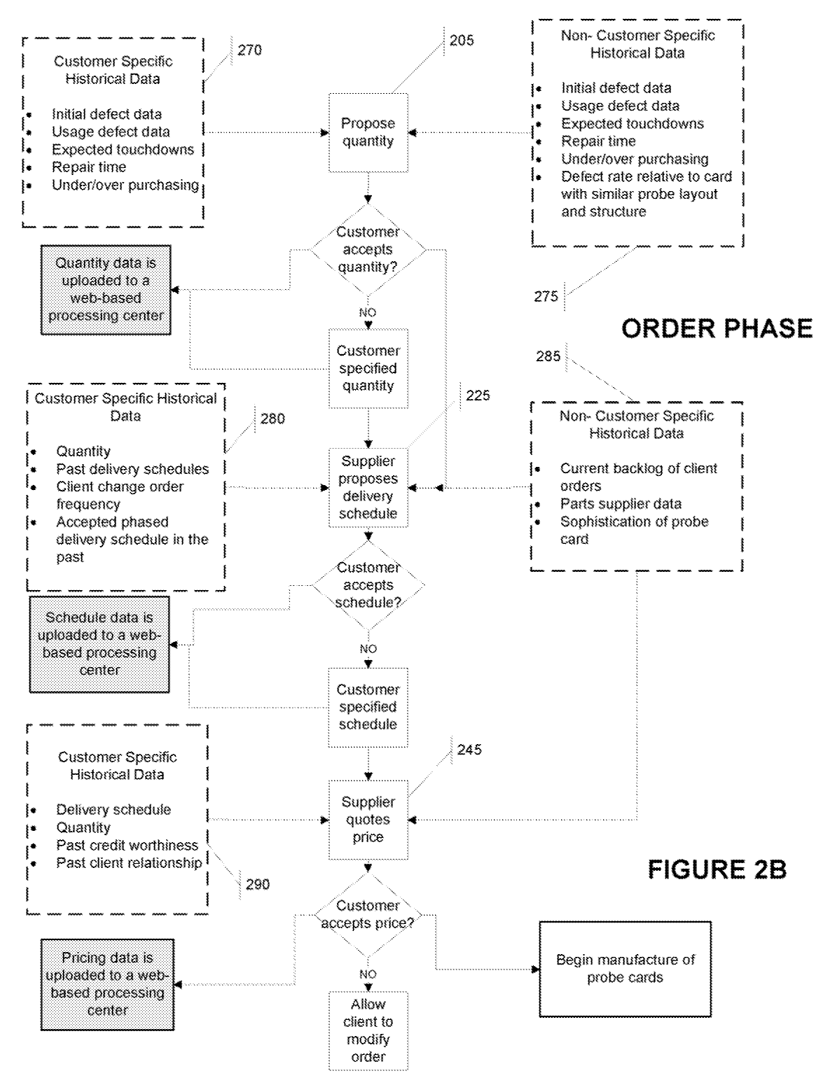

To optimize the structure, performance, and manufacture of a probe card for semiconductor wafer testing, a system is provided that coordinates the transmission, storage, and analysis of historical information from both the probe card supplier and customer. FIGS. 1A and 1B generally illustrate the significant events in the life of one probe card, from the time it is ordered to when it is retired. This overall timeline can be further divided into various phases, such as the order, manufacturing, performance, and repair phases which are discussed in greater detail with reference to FIGS. 2A through 5.

In addition to generally depicting the entire probe card timeline, FIGS. 1A and 1B illustrate the upload and download of key parameters and useful historical information to and from a web-based processing center, for the benefit of the customer and supplier using the information system. Both the customer and the supplier may upload data and view data that has been uploaded by the other party.

More specifically, information uploads and downloads are centralized in and accessible through a web-based processing center or other network. The order, manufacturing, performance, and repair information specific to one particular customer can be kept in an isolated database, or the information gleaned from one customer can be incorporated into a common database with information from various customers. This common database allows the supplier to compare common statistics across its customers, and to develop metrics for a more thorough comparison of the various probe cards it manufactures. Metrics are standardized computations performed on data from various customers to provide a statistical basis to compare the structure, performance, and manufacture of probe cards with different characteristics.

In a preferred embodiment, the probe card information system is configured to automatically and regularly calculate metrics based on the information provided by the supplier and its various customers. The system then compares the metric against historical data already stored in the system and communicates the results of this comparison to a specific customer and the supplier. Such metrics might include, but are not limited to, “Time between Probe Card Failures,” “Predicted Probe Card Lifespan,” “Predicted Probe Card Alignment Error,” and “Predicted Probe Card Failure per Wafer.” The unique advantage of using these and other metrics throughout the probe card timeline is discussed in greater detail below.

FIG. 1A depicts the entire probe card timeline and, more specifically, the uploading of useful information by the customer and the supplier to a web-based processing center. Non-shaded boxes depict discrete events in the probe card timeline, while shaded boxes indicate information uploads, specifically order, manufacturing, performance, and repair data.

Beginning at step (102), the customer begins the process of ordering a probe card from the supplier. At step (104), the supplier communicates with the customer on the probe card design, including such factors as the particular layout of the probe card and the number of probes needed on the card. If, at step (106), the customer wishes to change the initial order based on this communication, the customer is directed back to step (102) to revise the probe card order to conform with the desired changes. In the process, change order data is uploaded by either the customer or supplier to a web-based processing center at step (108), thereby capturing this information and providing a basis of comparison for all change order events for this customer.

If the customer does not have changes to the probe card order, the customer specifies a quantity and preferred delivery time at step (110). The final order data is captured at step (112), when either the customer or supplier uploads it to the web-based processing center. This enables specific details of this customer's final orders to be maintained in one central database, for later analysis and comparison. Thus, in quoting a price and delivery schedule at step (114), the supplier is informed by the final order terms for this current probe card order, as well as a historical record of past final orders from this customer. If the customer does not accept the price and delivery schedule terms at step (116), the customer specifies a new quantity and delivery time at step (118). Data generated by this ordering process is discussed in greater detail below, with reference to FIGS. 2A and 2B.

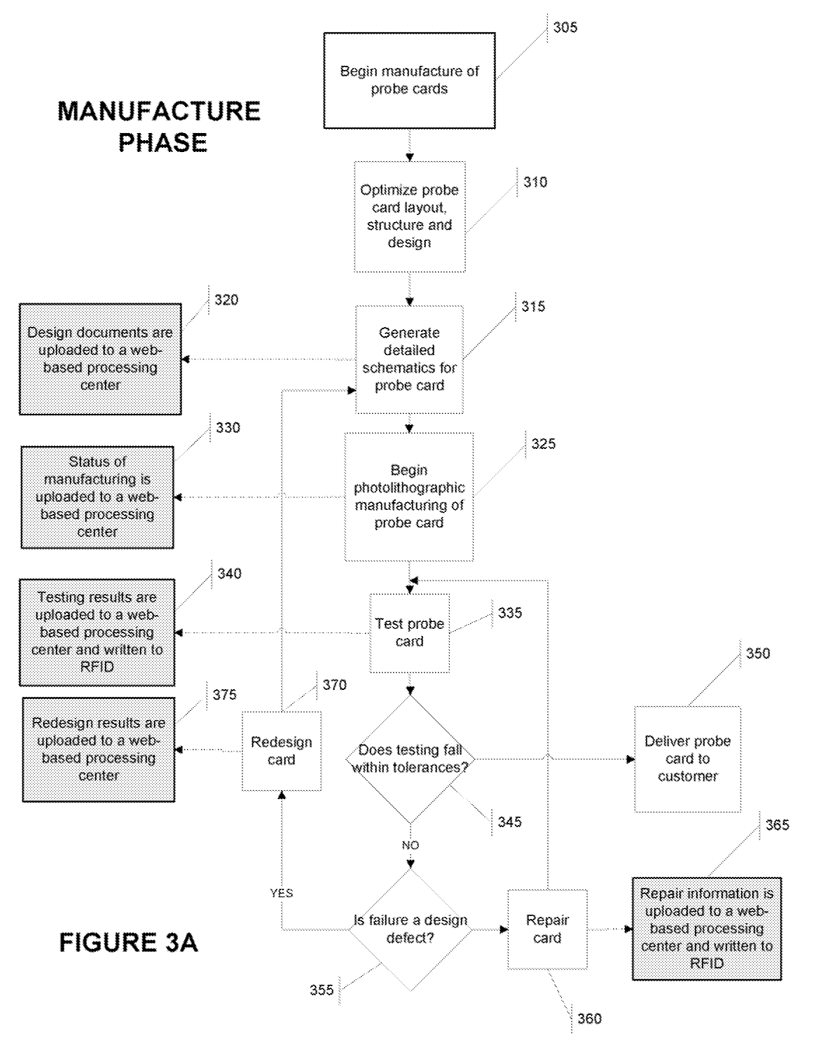

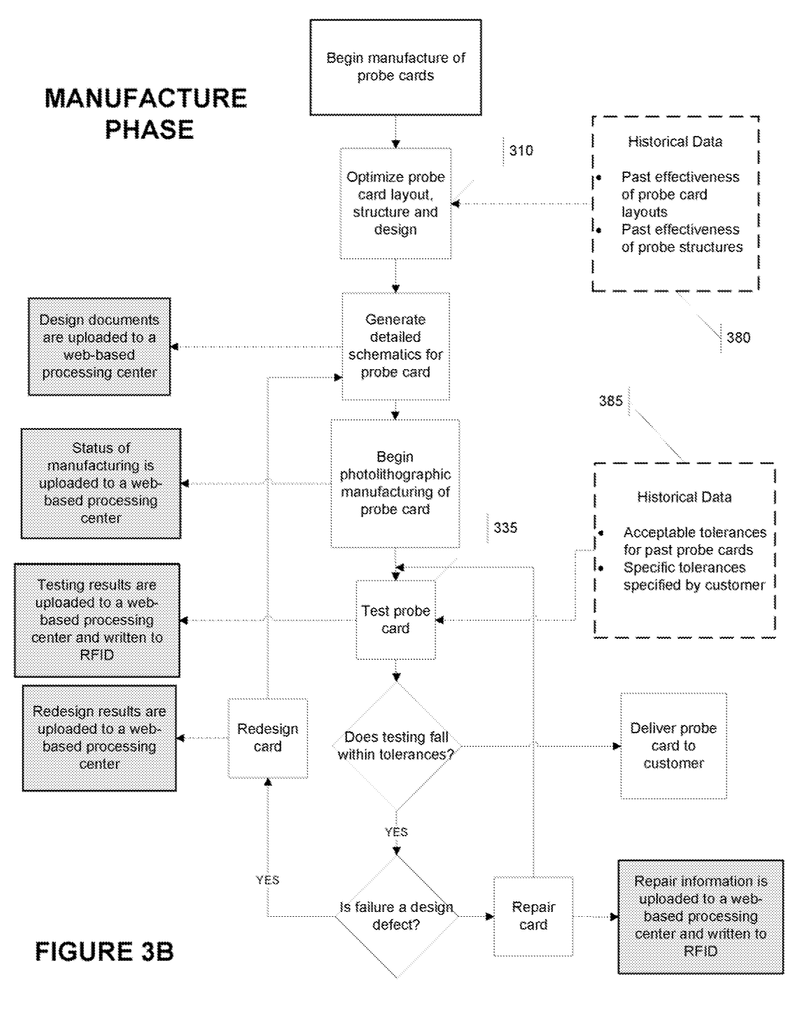

After the customer's final acceptance of the order terms, the final quantity and delivery terms are uploaded by the customer or supplier at step (120) and the probe cards are manufactured and delivered to the customer at step (122). As the probe card progresses through the manufacture phase illustrated at step (122), the supplier is simultaneously uploading status reports to the web-based processing center. These information uploads are depicted at step (124). Such status reports may include, but are not limited to, “Probe card substructure complete,” “Probe card diagnostic testing in progress,” “Probe card to be shipped in next 24 hours,” “Probe card shipped, Tracking #123.” This enables the customer a real-time view of where its probe card is in the manufacture phase, allowing the customer to make adjustments to its own manufacturing plans and processes and to assess daily the probability the probe card will be delivered on the anticipated date. Additional data generated in this manufacture phase is discussed in greater detail below, with reference to FIGS. 3A and 3B.

Upon taking delivery of the probe card, the customer performs a cursory review of the probe card and determines if it should be accepted at step (126). In addition to uploading the delivery receipt date and time, the customer uploads initial quality data obtained from its acceptance procedure to the web-based processing center at step (128). This upload gives the supplier access to two important pieces of information: 1) delivery data on this specific order, allowing it to assess its success in meeting its delivery schedule, and 2) initial acceptance test data for this specific probe card, allowing it to gauge the quality of its probe cards upon delivery. Prior to delivering the card to the customer, the supplier will test the card to determine if it meets the customer's tolerances/specifications. If the customer installs the new probe card incorrectly or damages it during installation, and claims it arrived defective, then an initial quality report saying “Probe card XYZ is working at time A, before installation,” could provide a basis for the supplier to say “No, the probe card was damaged after delivery. See initial quality report for Probe card XYZ.”

The probe card information system provides an even greater advantage in that, looking at this delivery and initial quality data over a sequence of probe card orders with this customer, the supplier can assess its manufacturing and delivery performance over a period of time. Instead of analyzing its performance in meeting the requirements of one discrete probe card order, the supplier is now equipped with trend data to target specific areas that require improvement.

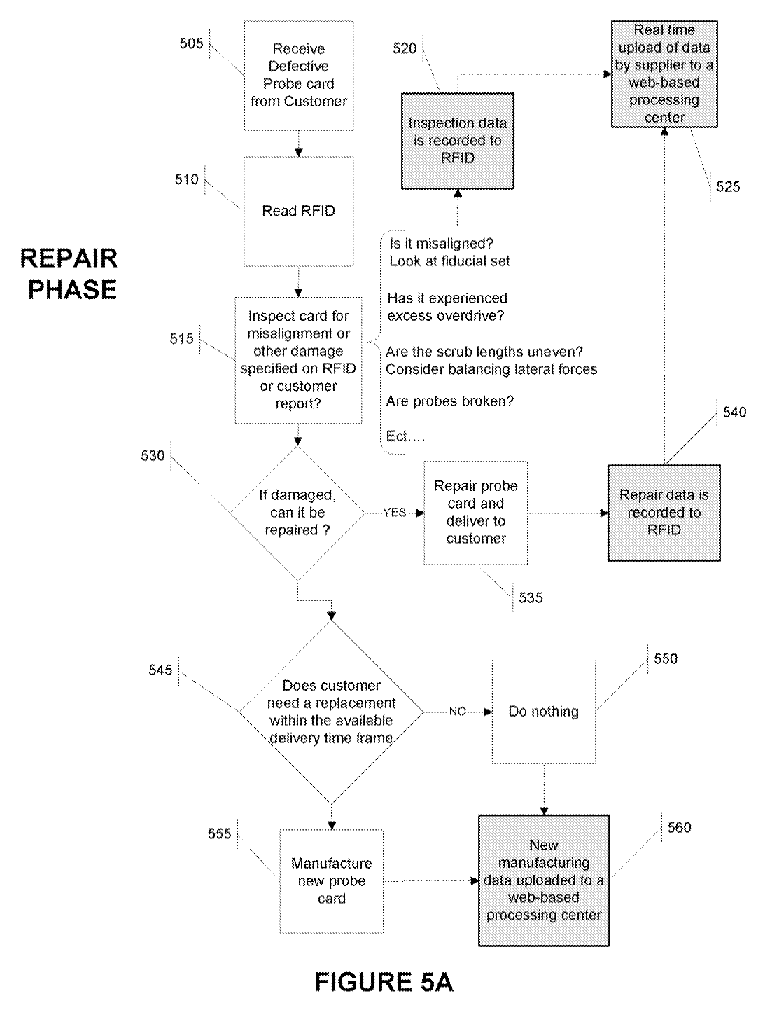

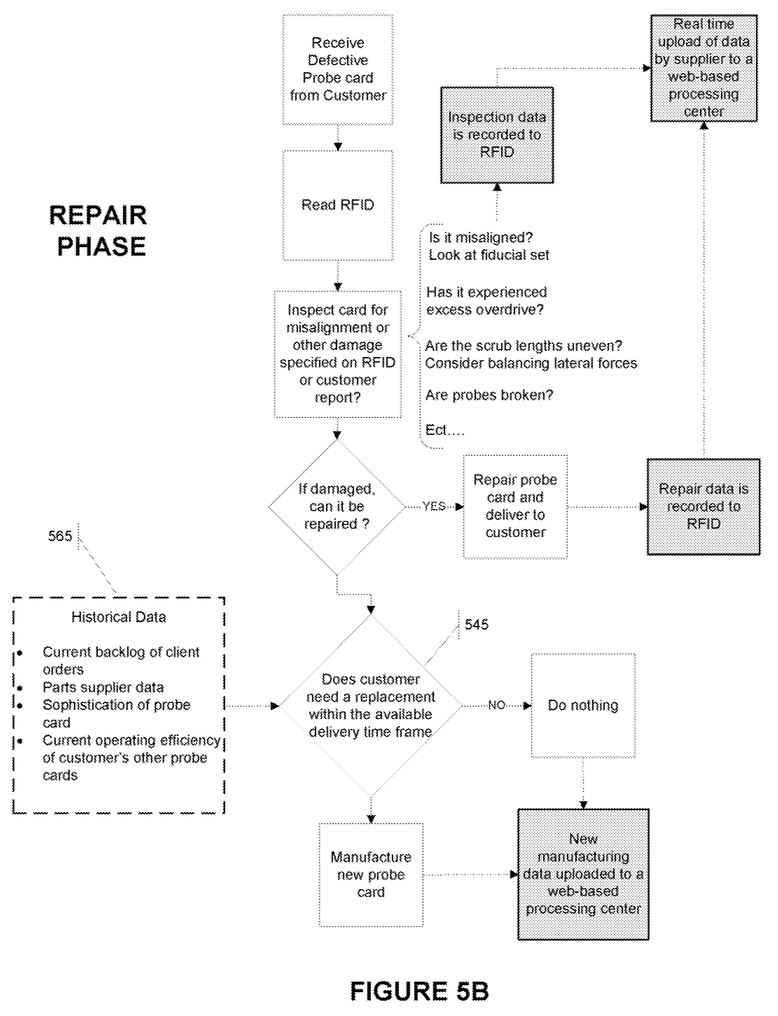

If the customer does not accept the probe card at step (126), it determines if it requires repair at step (130). If so, the customer returns the probe card to the supplier, who discovers and corrects the reason for rejection at step (132). The supplier uploads its findings at step (134), creating a record of the reason for rejection on this particular order, and, advantageously, another data point in the supplier's ongoing analysis of its manufacturing process. At step (136), the supplier repairs the probe card and delivers it to the customer. This repair process generates useful information that is captured at step (138), such as “name of engineer conducting repair,” “time to repair,” and “estimated delivery date.” This information gives the customer real-time updates on the progress of the repair. Additional data generated in this repair phase is discussed in greater detail below, with reference to FIGS. 5A and 5B.

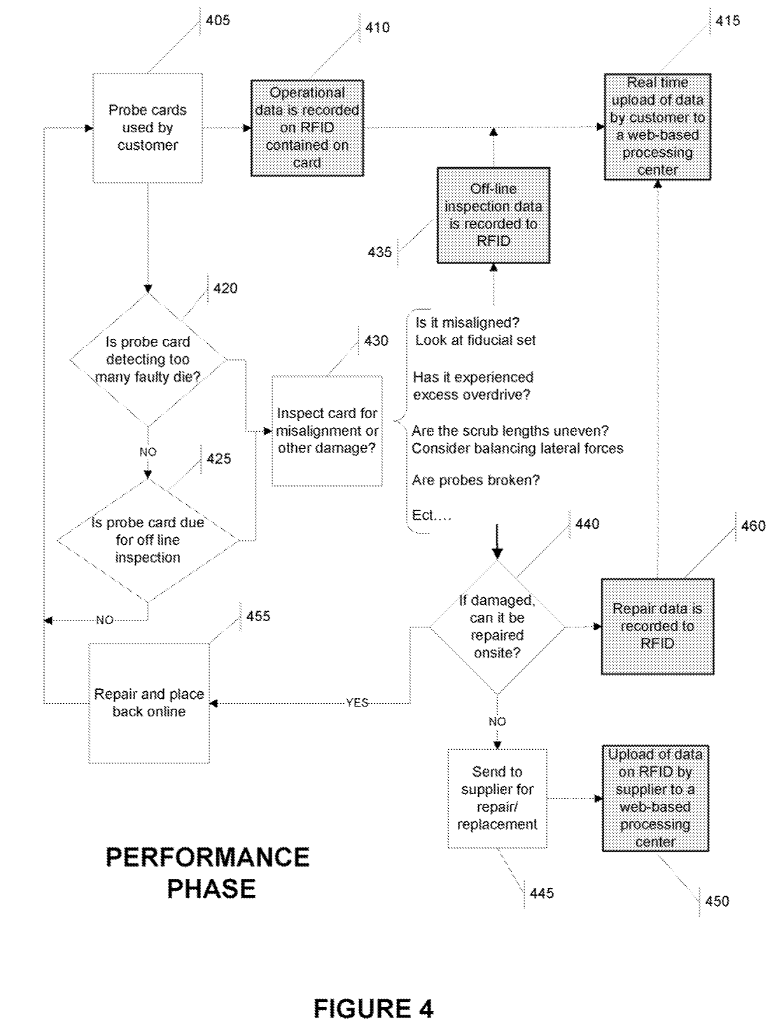

Once the probe card is finally accepted by the customer at step (126), the probe card is placed on-line and used until it is retired at step (140). Throughout the useful life of the probe card, performance data is uploaded by the customer to the web-based processing center at step (142). This performance data is discussed in greater detail below, with reference to FIG. 4. The probe card may also require repair after some period of use, in which case the probe card again enters the repair phase, discussed above and in greater detail with reference to FIGS. 5A and 5B.

When the probe card is retired at step (140) at the end of its useful life, the customer may reorder a new or replacement probe card at step (144). Probe card reorder data is uploaded by the customer at step (146), allowing the customer and supplier to track metrics such as “Time between probe card orders” and “Predicted probe card lifespan.” Such metrics can assist the supplier in planning and allocating its manufacturing resources among multiple customers, as well as alert the customer that it should consider placing a probe card order based on the historical performance of its current probe cards.

While FIG. 1A illustrates where valuable information in the order, manufacturing, and performance, and repair phases can be uploaded and stored for real-time decision making and later analysis, FIG. 1B illustrates where useful historical data may be introduced into these same phases through the use of information downloads. This incorporation of historical data at key steps in the timeline is depicted as information downloads in dashed boxes.

One such information download occurs at step (148). Here, the customer receives historical information about the specific characteristics of probe cards manufactured by the supplier at the point where such information is most useful: when the customer is about to place a probe card order with the supplier at step (102). As the customer and supplier communicate about the probe card design at step (104), the customer's decisions are also informed by historical data on prior probe card orders and designs at step (150). In an information download depicted at step (152), the customer learns quantity and delivery specifics of its previous probe card orders, helping it to specify a quantity and preferred delivery time for the current order at step (110). Finally, the supplier quotes a price and delivery schedule at step (114) with the aid of past price data imparted at step (154).

FIGS. 2A through 5 illustrate in greater detail the historical data that can be gleaned from, and introduced into, the order, manufacturing, performance, and repair phases of the overall probe card timeline depicted in FIG. 1A. FIGS. 2A and 2B depict in greater depth the order phase in this timeline, corresponding with steps (110) and (114) in FIG. 1A, whereby the customer and supplier determine the parameters of the probe card order. In FIG. 2A, non-shaded boxes illustrate discrete events in the ordering process, while shaded boxes indicate uploads of customer data.

The order phase begins after the probe card design has been finalized, at which point the supplier proposes a quantity of probe cards to be manufactured at step (205). The customer may accept the proposed quantity at step (210), or reject it and specify a different quantity at step (215). In either case, the final agreed-upon quantity data is uploaded by the customer or the supplier to a web-based processing center at step (220). At step (225), the supplier proposes a delivery schedule, which the customer accepts or rejects at step (230). If the customer rejects the proposed schedule, a customer-specified schedule is provided at step (235), and the corresponding schedule data is uploaded by the customer or the supplier to the web-based processing center at step (240). The supplier then quotes a price at step (245), based in part on the quantity and schedule parameters established earlier in the timeline. If the customer accepts the quoted price at step (250), the final pricing data is uploaded to the web-based processing center by the customer or supplier at step (255), and the supplier begins to manufacture the probe cards at step (260). If the customer does not accept the price quote at step (250), the customer may modify the probe card order at step (265).

The benefits of the information uploads in steps (220), (240), and (255) are fully understood with reference to FIG. 2B. Capturing and storing the quantity, delivery, and pricing data of one probe card order provides one data point along a continuum of probe card orders, allowing the supplier and customer to review a historical record of these parameters and to use trend data to inform future decisions. This inclusion of historical data in the decision-making and negotiating process is depicted in FIG. 2B as information downloads in dashed boxes.

The first decision informed by such an information download is step (205). Customer-specific historical data is downloaded at step (270), equipping the supplier with valuable information that allows it to put together a more informed, and thus more efficient and useful, quantity proposal. Such historical data can include, but is not limited to, information on the number and type of defects typically experienced by this particular customer when it initially receives probe cards of the type currently being ordered, as well as information on the defects the customer has historically experienced throughout the useful life of this type of probe card. The customer can also be provided data at step (270) on the number of touchdowns it historically expects, and previous repair times it has typically experienced, with this particular type of probe card.

An additional piece of information that helps both the supplier and customer in determining the optimal quantity of probe cards to order is whether this customer has a history of over or under purchasing probe cards. For example, the historical data may show that when this particular customer orders this type of probe card, it underestimates its requirements and only orders an average of three probe cards per order. When the customer is forced to order, on average, two more probe cards to meet this unanticipated need, the supplier must devote additional, unplanned resources to meet the customer's short delivery schedule. Conversely, this particular customer may have a history of ordering too many probe cards when it orders this type of probe card, causing the supplier to use its resources inefficiently to meet this customer's demands instead of those of another customer.

Historical data that is not specific to this particular customer can also help the supplier and customer determine the optimal number of probe cards to order. At step (275), for example, information on the number and type of defects typically experienced by all of the supplier's customers is incorporated into the decision on what quantity of probe cards this particular customer should purchase. Such defect information can include, but is not limited to, initial defect data captured and uploaded when the customers first conduct quality checks on new probe cards, and defect data uploaded by customers throughout the useful life of their probe cards. Similarly, the customer that is currently placing an order can be provided with statistics on the touchdowns that other customers historically expect with this kind of probe card, the repair times they typically experience with these probe cards, and other customers' tendencies to over or under purchase this type of probe card.

Finally, because the probe layout and structure of probe cards will vary from customer to customer, defect information provided at step (275) can also be tailored such that the customer is given the defect rate of probe cards of a similar structure and design to that which the customer is currently ordering. For example, the supplier may be informed the customer intends to make 100,000 wafers and needs probe cards capable of completing 120,000 touchdowns. With information downloaded at step (275), the supplier can inform the customer that similar probe cards have an expected lifespan of 10,000 touchdowns and that it should therefore order ten to twelve probe cards. Thus, as a result of this customer-specific and non-customer-specific historical data provided at steps (270) and (275), the supplier and customer are positioned to make well-informed quantity decisions at steps (205) and (210).

Historical data specific to this particular customer can also be analyzed by the supplier at step (280), helping the supplier propose a realistic and satisfactory delivery schedule at step (225). Given the quantity of probe cards the customer has requested in this order, information on this customer's past delivery schedules, and the frequency with which this customer has changed its orders, the supplier can best assess what delivery schedule it can commit to on this order. If the customer has previously accepted a phased delivery schedule, agreeing, for example, to accept two probe cards every two weeks when it has ordered this particular kind of probe card in the past, the supplier will also have access to this historical information at step (280).

Information downloaded at step (275) can also help determine the timing of a phased delivery schedule. For example, suppose the supplier has generally agreed to deliver three probe cards to the customer in the next five to six weeks. Historical data reveals the probe cards have a typical lifespan of 10,000 touchdowns and that it typically takes the customer two weeks to achieve 10,000 touchdowns. Based on this historical information and anticipated usage rate, the supplier can propose to initially deliver two probe cards to the customer and then wait four weeks before delivering the third probe card. This phased delivery allows the supplier to more optimally allocate manufacturing resources among its customers. The customer benefits by staggering its payments based on the phased delivery schedule, and, if defects are discovered in the first two probe cards the customer receives, the customer can make changes to the third probe card in its order.

In addition, at step (285), the supplier can access information that is not specific to this particular customer but is still of great value in creating an achievable delivery schedule for the customer. For example, the supplier can incorporate information on its current backlog of customer orders, data from its parts supplier, and the degree of sophistication of this specific probe card into its delivery estimate. If the supplier concludes the current backlog is high, a key part is unavailable from its part supplier, or this particular kind of probe card has historically required two additional weeks for manufacturing and testing, the supplier can propose a delayed or phased delivery at step (225). Thus, significant time and cost savings can be realized by the use of customer-specific and non-customer-specific historical data at steps (280) and (285).

At the end of the order phase, the supplier quotes a price at step (245) in light of customer-specific historical data provided at step (290). Taking such information as the quantity and delivery schedule for this order, the customer's past credit worthiness, and the client relationship the supplier has with this customer, the supplier is in a position to provide a reasonable price quote for this probe card order. The addition of this information to the supplier's decision-making process benefits the supplier and the customer, as it reduces the likelihood the client will reject the price quote or modify the order, and allows the supplier to begin manufacture of the probe cards faster and with greater assurance of customer satisfaction.

FIGS. 3A and 3B illustrate the manufacture phase, which corresponds to step (122) in FIG. 1A. Like the order phase, the manufacture phase is optimized by analyzing key historical data acquired during earlier manufacture phases. Referring now to FIG. 3A, non-shaded boxes illustrate discrete events in the manufacturing process, while shaded boxes indicate uploads of supplier data.

After accepting a final probe card order from the customer, the supplier begins the manufacturing process at step (305). The probe card layout, structure, and design are optimized at step (310), and detailed schematics are generated at step (315). The supplier uploads these detailed design documents to a web-based processing center at step (320), which the customer can access and view. At step (325), the supplier begins photolithographic manufacturing of the probe card, and simultaneously uploads regular status reports to the web-based processing center at (330). Such status reports may include, but are not limited to, “Probe card substructure complete,” “50% of probes on probe card,” and “Final probe adjustments complete.”

The supplier next tests the completed probe card at step (335), and uploads these test results to the web-based processing center at step (340). In addition, these test results may be written to a storage device that is designed to accompany the probe card throughout its useful life, or in a preferred embodiment, is permanently contained in the specific probe card. Such a storage device could include, but is not limited to, a radio frequency identification (RFID) tag that can store data specific to the probe card, and from which such data can easily be accessed. If the supplier determines the testing results are within tolerance at step (345), the probe card is delivered to the customer at step (350). Otherwise, the supplier assesses whether the failure is a design defect at step (355). If the testing failure is not due to a design defect, the probe card is repaired at step (360), with the corresponding repair information being uploaded to the web-based processing center by the supplier at step (365). This repair information is also written to the probe card's RFID tag or other storage device. If the testing failure is due to a design defect, the supplier must redesign the card at step (370). This event generates data which is captured at step (375), when the supplier uploads the redesign results to the web-based processing center.

The customer can access and view the information uploads depicted at steps (320), (330), (340), (365), and (375). This allows the customer to track the progress of the manufacture and testing of its probe card, to be quickly and accurately informed of any testing failures or the need to redesign the card, and to assess the likelihood the probe card will be delivered in accordance with the delivery schedule.

In addition to uploading manufacturing data specific to this customer throughout the manufacture phase, the supplier benefits from the download of valuable historical data at key steps in the manufacturing process. These information downloads, depicted in dashed boxes in FIG. 3B, give the supplier additional knowledge about the manufacturing process that can affect the manufacture of this particular probe. Take, for example, step (380), where the supplier is equipped with historical data on the past effectiveness of various probe card layouts and structures at the point where having such information is most advantageous: when the supplier is optimizing the layout, structure, and design of the probe card it is about to manufacture. Suppose the customer proposes a very complicated probe card layout that requires a specific type of probe card structure. With the benefit of historical information downloaded at step (380), the supplier can assess this proposal and determine that the proposed probe card structure fails more often than a simpler probe card structure. Armed with statistical data to back up its assertions, the supplier can inform the customer of the limitations associated with its proposed probe card structure, such as an excessive number of probes or an inability to make the probe card thick enough to withstand tortional forces, resulting in a shortened lifespan with 30% fewer touchdowns than a simpler probe card. Thus, historical data is harnessed to optimize the present manufacture and future performance of the customer's probe cards.

Concurrent with probe card testing at step (335), the supplier can incorporate historical data on the acceptable tolerances of past similar probe cards and the specific tolerances specified by the current customer at step (385). The information downloads the supplier might find useful during the manufacturing process are not limited to these examples, however. The data uploads discussed with reference to FIG. 3A, namely the design documents, manufacturing progress reports, testing and redesign results, and repair information that were uploaded in prior manufacturing runs, can also help the supplier gauge its progress in the current manufacturing run.

The collection and use of valuable information continues into the performance phase of the probe card timeline. This phase, illustrated in step (140) in FIG. 1A, begins after the supplier delivers the probe card to the customer and the probe card enters operational use. FIG. 4 depicts the performance phase in greater detail, with non-shaded boxes representing discrete events in the performance phase and shaded boxes indicating uploads of customer data.

Beginning at step (405), the probe card is used by the customer. Operational data is recorded on the RFID tag or other storage device that is contained on the probe card at step (410), with data entries occurring at periodic intervals throughout the probe card's useful life. This raw performance data can also be used to calculate such metrics as “Time between Probe Card Failures” and “Predicted Probe Card Failure per Wafer.” These metrics calculations can later serve to assist the supplier and the customer in determining how many and what type of probe cards the customer should order. A “Monthly Touchdowns” metric can also be calculated by dividing the total number of touchdowns generated on one supplier's probe cards, for one device type, in one month by the total number of probe cards built by that supplier for that device type. This metric allows the supplier and customer to compare the performance characteristics of probe cards from different suppliers, a comparison which typically cannot be made without metrics. The customer can also use this metric to predict, based on it current probe card utilization, the number of probe cards it will need to order from a given supplier to support its output demands. In addition, the customer may determine that, based on the monthly touchdowns of its probe cards, it has not utilized a particular probe card to its full potential and can get more touchdowns out of the probe card each month. Thus, these metrics greatly benefit the customer, as the more accurate these usage and ordering predictions are, the fewer probe card shortfalls and costly downtime the customer will experience.

In addition to writing real-time performance data to the probe card RFID at step (410), the customer uploads the performance data to a web-based processing center at step (415). The information system can also be configured to perform these performance data uploads automatically. The uploads at step (415) allow the supplier to track the probe card's performance and quality while the probe card is in use, not just after it is taken off-line and returned to the supplier.

At step (420), the customer assesses if the probe card is detecting too many faulty die. It is important for the customer to detect this kind of problem quickly, as a high detection rate could mean the probe card is faulty or has reached the end of its useful life, or it could mean the customer is manufacturing a disproportionate number of defective die. By reading the RFID or other storage device contained on the probe card or by accessing a record of the probe card's performance through the web-based processing center, the customer determines if the probe card is due for an off-line inspection at step (425). If the probe card is not due to be taken off-line for an inspection, the customer returns to step (405) and continues using the probe card. Otherwise, the customer takes the probe card off-line and inspects it for misalignment or other damage at step (430). In the course of this assessment, the customer may inspect the probe card's fiducial set to determine if the probe card is misaligned. The customer also determines whether any probes are broken, whether the probe card has experienced excess overdrive, and whether the scrubs lengths are uneven (and, if so, whether to balance lateral forces). The findings of this off-line inspection are recorded to the RFID tag or other storage device at step (435), and, at the same time, the customer uploads the inspection results to the web-based processing center at step (415). This again allows the supplier real-time access to the same performance data the customer has access to, enhancing communication between the supplier and customer on the resolution of this probe card's deficiencies and the design of future probe cards.

This raw inspection data can also be used to calculate metrics such as “Predicted Probe Card Alignment Error.” Similarly, a “Radial Error per Number of Probes per Number of Touchdowns” metric can be calculated by dividing the average alignment error vector by the number of touchdowns of the probe card. Such metrics can help the supplier recommend a particular type of probe card structure to the customer, as well as assist the customer in assessing the cost-benefit tradeoffs of using a particular type of probe card.

If the off-line inspection reveals that the probe card is damaged, the customer determines, possibly in consultation with the supplier, if the probe card can be repaired at the customer's site at step (440). If the probe card cannot be repaired onsite, the customer sends it to the supplier for repair or replacement at step (445). Upon receipt of the faulty probe card, the supplier uploads the data stored on the probe card's RFID or other storage device to the web-based processing center at step (450), ensuring the data stored at the processing center and on the RFID tag matches. Step (445) begins the repair phase of the probe card timeline, which is discussed in greater detail with reference to FIGS. 5A and 5B.

If the probe card can be repaired on site, the customer conducts the repair at step (455) and records the resulting repair data to the RFID or other storage device contained on the probe card at step (460). The writing of performance and repair data to the probe card's RFID tag or other storage device ensures a performance and repair history accompanies the probe card at all times, allowing effortless retrieval of this useful information while the probe card is on-line and in use. In addition, the customer uploads the same repair data to the web-based processing center at step (415), thus keeping the on-line record of the probe card's performance constantly updated. Thus, by accessing the web-based processing center, the supplier can observe when the repaired probe card is placed back online and brought back to full use at step (405).

It is important to note that the information uploads that occur during the performance phase just described provide the statistics by which valuable performance metrics can be calculated. The probe card data used to calculate such metrics include, but are not limited to, planarity, alignment, contact resistance, leakage, probe tip diameter, number of touchdowns per probe card, failures, and various combinations of these parameters. For example, the performance data uploaded at step (415) can be used to calculate a “Failures per Touchdown per Probe Card” metric, allowing the customer to compare the performance of probe cards manufactured by different suppliers, even if the suppliers do not have the same number of touchdowns or the same number of probe cards.

Useful historical information is also introduced into the repair phase of the probe card timeline. This phase, illustrated in steps (132) and (136) in FIG. 1A, only occurs if a customer does not accept a probe card upon delivery or cannot repair a probe card that is damaged during use, and must return it to the supplier for repair. FIG. 5A depicts the repair process in detail, with non-shaded boxes representing discrete events in the repair timeline and shaded boxes indicating uploads of customer data.

Beginning at step (505), the supplier receives the defective probe card from the customer. The supplier reads the RFID tag or other storage device contained in the probe card at step (510). Equipped with data from the RFID tag and the customer's online damage report, the supplier inspects the probe card for misalignment or other damage at step (515). In addition to examining the probe card's fiducial set to determine if the probe card is misaligned, the supplier also determines if any probes are broken, whether the probe card has experienced excess overdrive, and whether the scrubs lengths are uneven. Data generated from this inspection is recorded to the probe card's RFID or other storage device at step (520), and the supplier also performs real-time uploads of the inspection information to the web-based processing center at step (525). This upload of inspection information keeps the customer informed as to the progress of repairs on its probe card, allowing it to assess when the probe card might be returned to operational use and whether additional probe cards should be ordered due to excess repair times.

If the probe card is damaged, the supplier determines at step (530) if it can be repaired. If so, the supplier performs the repairs and delivers the probe card to the customer at step (535). Before delivery, however, the supplier records data generated by the repair on the probe card's RFID or other storage device at step (540), continuing to keep the probe card's attached performance record current throughout its useful life. In addition, the supplier uploads the same repair data to the web-based processing center at step (525), so that the customer can access and use this information before the repaired probe card is re-delivered to the customer. This information upload at step (525) also ensures that if the RFID tag or other storage device contained in the probe card experiences a fault, and cannot be read or accessed, there is a back-up of all performance data for the probe card in a separate location.

If the probe card cannot be repaired at step (535), the supplier determines if the customer requires a replacement probe card within the available delivery time frame at step (545). If the customer does not need a replacement card, the supplier retires the damaged probe card at (550) and takes no further steps. If, on the other hand, the customer does require a replacement card, the supplier begins manufacture of a new probe card at step (555). In either case, at step (560) the supplier uploads information on its action, whether it be retirement of the card or manufacture of a new card, to the web-based processing center.

Various historical data captured throughout the useful life of this customer's probe card, as well as useful supplier-based information uploaded to the web-based processing center, enhance the repair process just discussed. FIG. 5B illustrates one such introduction of this data into the repair process, thus allowing the supplier and customer to make informed decisions about the best course of action at each step in the process. At step (565), depicted in a dashed box indicating an information download, the supplier assesses its current backlog of client orders, the availability of parts from its parts supplier, the sophistication of the damaged probe card, and the current operating efficiency of the other probe cards the customer has on hand. This information, taken together, allows the supplier to determine if the customer needs a replacement probe card, and if a replacement can be delivered within the available delivery time frame. Both the supplier and customer benefit from the inclusion of this information in the supplier's decision-making process, as the supplier can make a replacement recommendation with confidence that the customer's needs will be met, while the customer appreciates the supplier is taking all relevant factors into account in making its recommendations.

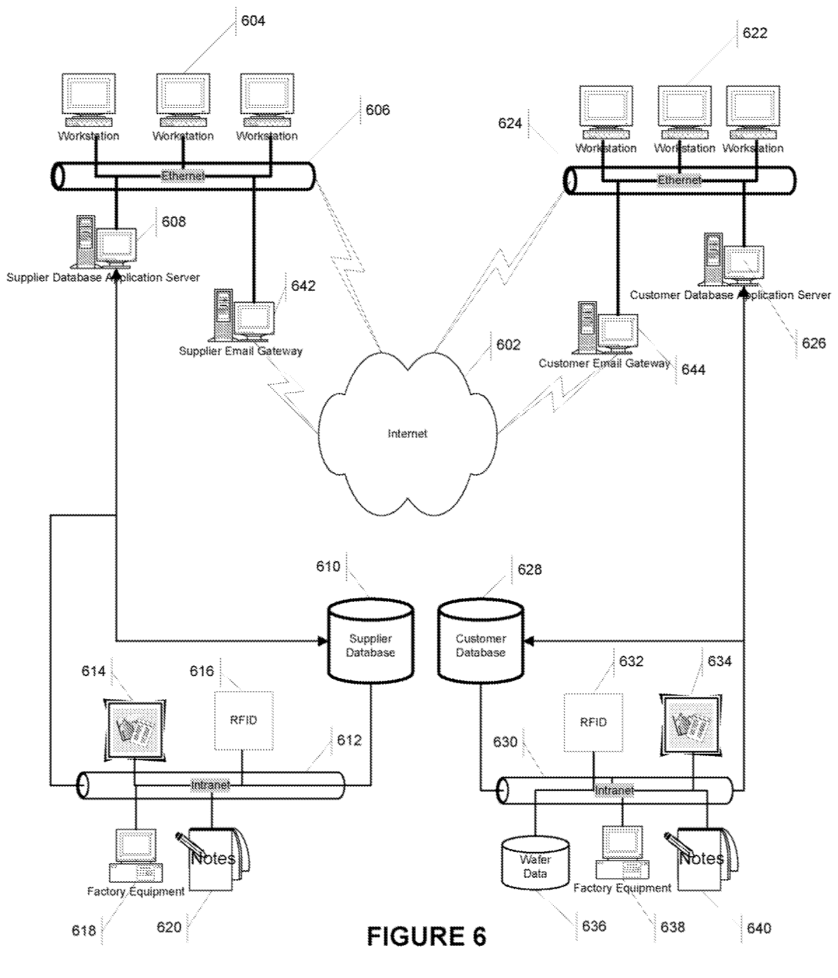

Referring now to FIG. 6, a web-based system is illustrated whereby the probe card information just described is shared over a network between the supplier and customer, such that both parties can upload information to, and retrieve information from, a web-based processing center. A person of ordinary skill in the art will understand the system is not limited to the system illustrated in FIG. 6, as other systems and configurations can achieve this information-sharing function.

In a preferred embodiment, the web-based information system uses the Internet (602) to facilitate the storage and exchange of information from the supplier and customer. First, the supplier uploads information on the structure, manufacture and performance of probe cards at supplier workstations (604). The workstations are connected to each other and a supplier database application server (608) through supplier Ethernet (606). This Ethernet connection allows the information uploads to be securely stored on, and accessed from, the supplier database application server (608). The supplier database application server (608) stores the information uploads in a supplier database (610). Thus, the supplier can access previously-uploaded information on the structure, manufacture, and performance of probe cards from the supplier database (610) by logging on to a supplier workstation (604) and accessing the supplier database (610) through the supplier database application server (608).

In a preferred embodiment, the supplier database application server (608) is equipped with an application that provides a graphical user interface by which the supplier can easily input order, manufacture, performance, and repair information at the supplier workstation (604). The graphical user interface may consist of, but is not limited to, webpages for inputting and transferring information over the Internet (602) or other network.

In addition to information inputted at supplier workstations (604), the supplier database stores information uploaded to it via the supplier intranet (612). Such information can include, but is not limited to, probe card schematics (614), RFID tag readouts (616), factory equipment data (618), and supplier notes (620).

The web-based information system can be configured to upload probe card data inputted at supplier workstations (604) and supplier intranet (612) automatically. This automatic upload feature enhances the utility of the system, ensuring more regular and accurate uploads than if the information were uploaded manually by a technician tasked with performing the uploads. The system can also be configured to download probe card data automatically when the supplier accesses the system to make certain ordering, manufacturing, performance, or repair decisions about its probe cards. This feature is particularly useful, as valuable historical information relevant to the decision the supplier is about to make will automatically download and appear on the workstation monitor, triggered by the supplier accessing a particular section of the web-based information system.

The web-based system can also be configured to calculate metrics automatically, whereby the system receives information uploaded by the supplier, calculates a metric based on this information, compares the metric against historical data stored in the system, then communicates the results of this comparison to the supplier. Like the download of raw historical information noted above, the results of automatic metric calculations can be configured to appear at the workstation monitor when the supplier accesses a particular section of the web-based information system. However, unlike downloads of raw historical data, automatic metric calculations have the additional benefit of synthesizing large quantities of historical data into particularly useful statistics that encompass data across all customers, not just this particular customer.

Like the supplier, the customer uses an information storage and retrieval system to catalogue probe card and wafer data. It inputs information on the structure, design, and performance of the probe cards it uses at customer workstations (622). The workstations are connected to each other and a customer database application server (626) through customer Ethernet (624). This Ethernet connection allows the information uploads to be securely stored on, and accessed from, the customer database application server (626). The customer database application server (626) stores the information uploads in a client database (628). Much like the supplier, the customer can access previously-uploaded information on the structure, design, and performance of probe cards from the customer database (628) by logging on to a customer workstation (622) and accessing the customer database (628) through the customer database application server (626).

The customer database also stores information uploaded to it via the customer intranet (630). Such information can include, but is not limited to, RFID tag readouts (632), probe card design drawings (634), wafer data (636), factory equipment data (638), and customer notes (640).

Like the supplier's information system, the customer system can also be configured to conduct automatic uploads and downloads of probe card data. The results of automatic metric calculations are also advantageously displayed on the customer workstation (622) when the system detects such information would be useful to the customer.

Thus, both the supplier and customer have self-contained information systems that can store, and from which they can access, valuable information on their processes. But the supplier's information is valuable to the customer as well, and vice versa. The supplier and customer can access each other's probe card information through an Internet connection. In addition to being connected to the supplier database application server (608), the supplier Ethernet (606) is connected to supplier email gateway (642). Similarly, the customer Ethernet (624) is connected to customer email gateway (644). The supplier and customer email gateways may be connected via the Internet (602), thus allowing the supplier to access information stored on the customer database (628) and vice versa. It is also possible to connect the supplier and customer databases directly to the Internet (602) without passing through the email gateways (642 and 644). Various encryption mechanisms can ensure the security of information stored on, and accessed from, the supplier database (610) and customer database (628). For example, data can be transferred via encrypted emails from one email gateway to another, thus ensuring the integrity of supplier and customer data as it is transferred over the Internet.

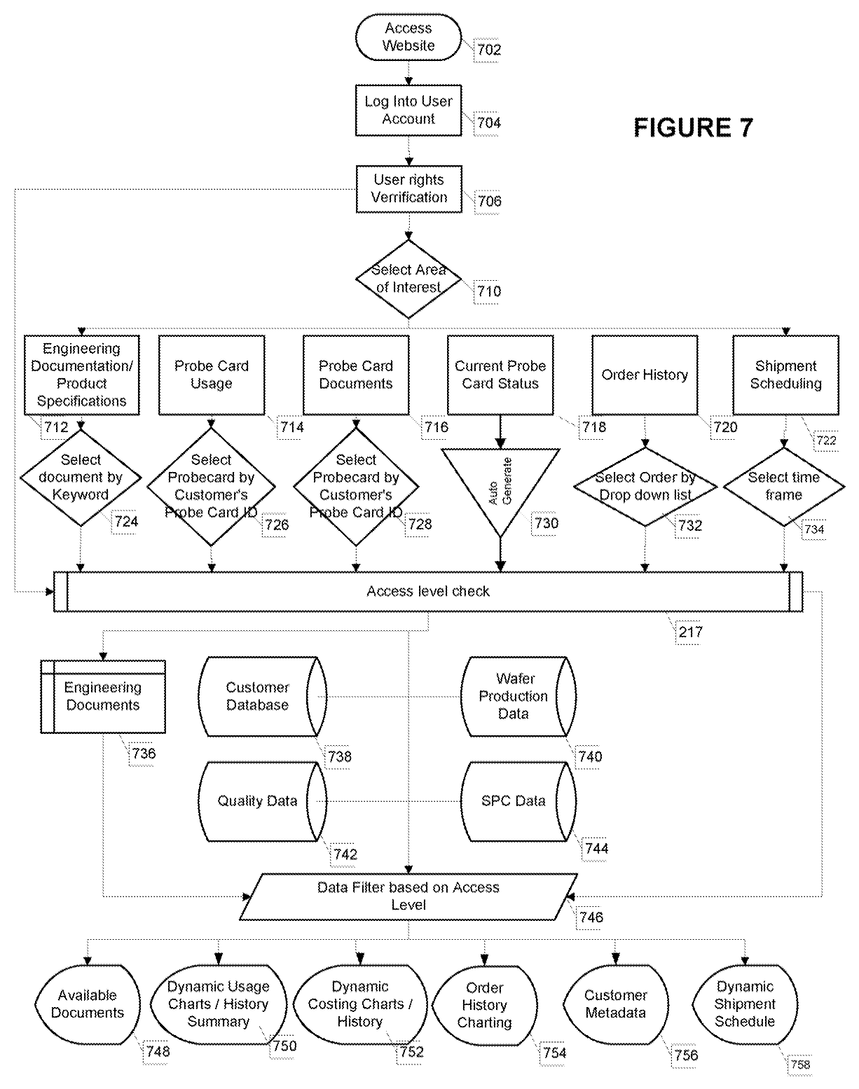

FIG. 7 illustrates in greater detail the process by which the customer can store or retrieve information from the web-based processing center that is connected to both the customer's data and the supplier's data. At step (702), a customer user accesses a website that interfaces with the web-based processing center. The customer user logs into its account at step (704), and to ensure the security of data stored on the web-based system, a user rights verification is performed at step (706). In addition to authenticating the user has the correct log-in information, the user rights verification at step (706) also allows the system to perform an access level check (708). This access level check allows the system to identify what type of information this particular user is authorized to access. For example, the customer may give account access to numerous employees, but choose to give officers of the company full access to all information stored on the web-based system, while setting permissions for engineers to access engineering data only.

Having verified its user rights and access level, the user selects an area of interest at step (710). The means to select an area of interest may include, but is not limited to, a user-friendly drop-down menu. Such areas of interest may include, but are not limited to, engineering documentation and product specifications (712), probe card usage data (714), probe card documents (716), current probe card status (718) (which may include status of probe cards currently used on the production line or the status of probe cards that are currently being manufactured by the supplier), order history (720), and shipment scheduling (722).

Based on the area of interest that is selected, either the user is requested to provide further information or the web-based system proceeds to auto-generate a report. For example, if the user wishes to access probe card usage (714) or probe card documents (716), the system requires the user to input a customer probe card identification number. This identification number allows the system to identify the various probe cards currently in use by this customer. From this list of probe cards currently in use, the user can select the specific probe card for which usage data or documents are desired at steps (726) and (728). If the user wishes to access engineering documents or product specifications (712), the user can select the document by using a keyword at step (724). Similarly, to access an order history (720), the user must select an order from a drop-down list at step (732). To review a shipment schedule (722), the user selects a time frame at step (734). Finally, if the user wishes to view the current status of all probe cards (718), the system will auto-generate a status report at step (730).

Should the user wish to access more sensitive data that is protected at a higher level, the system uses the access level check (708) to determine what level of information the user has permission to view. For example, an engineer may only have access to view engineering documents (736). On the other hand, an employee with full access rights may be given access to review information stored on the customer database (738), probe card production data (740), wafer and probe card quality data (742), and statistical process control “SPC” data (744). Because the system is customized to meet the needs of this particular customer, many different types of data other than those just listed can be accessed through the customer website.

Finally, detailed or sensitive reports and records can also be made available through the web-based processing center. This information can be protected from unauthorized access through the use of a data filter (746) that is set based on the access level check (708). The detailed information can include, but is not limited to, available documents (748), dynamic usage charts and history summary (750), dynamic costing charts and history (752), order history charts (754), customer metadata (756), and dynamic shipment schedules (758).

Having described the methods and structures in detail and by reference to several preferred embodiments thereof, it will be apparent that modifications and variations are possible without departing from the scope of the invention defined in the following claims. Moreover, the applicant expressly does not intend that the following claims “and the embodiments in the specification to be strictly coextensive.” Phillips v. AHW Corp., 415 F.3d 1303, 1323 (Fed. Cir. 2005) (en banc).

1. An information system for optimizing a phase in the lifespan of a probe card comprising:
at least one server coupled to a network wherein the server receives, stores and
disseminates historical data relating to said phase from a plurality of probe cards;
an application operable with said server to provide functions comprising:
(a) receiving over said network from a probe card customer and supplier current information relating to said phase in the life of a probe card;
(b) calculating a metric based on the information provided by the customer and supplier;
(c) comparing the metric against the historical data; and
(d) communicating the results of the comparison in step (c) and the historical data to a user.

2. The system of claim 1 wherein the optimized phase is the phase during which a probe card is ordered by a customer from a supplier.

3. The system of claim 2 wherein the current information is selected from a group consisting of: quantity, delivery schedule, price, client order backlog, parts supplier data, probe card sophistication and combinations thereof.

4. The system of claim 2 wherein the historical data is selected from a group consisting of: quantity, phased and non-phased delivery schedule, price, probe card sophistication, initial defects, usage defects, expected touchdowns, repair time, under and over purchasing, client change order frequency, client credit worthiness, client relationship and combinations thereof.

5. The system of claim 2 wherein the metric is selected from a group consisting of: time between probe card orders, predicted probe card lifespan, predicted initial defect rate, predicted usage defect rate, average schedule delay, predicted phased delivery success rate, schedule change frequency and combinations thereof.

6. The system of claim 1 wherein the optimized phase is the phase during which a probe card is manufactured by a supplier.

7. The system of claim 6 wherein the current information is selected from a group consisting of: design documentation, manufacturing status reports, tolerances specified by the customer, testing results, redesign results, repair reports and combinations thereof.

8. The system of claim 6 wherein the historical data is selected from a group consisting of: effectiveness of probe card layouts, effectiveness of probe card structures, acceptable probe card tolerances and combinations thereof.

9. The system of claim 6 wherein the metric is selected from a group consisting of: predicted manufacturing time, predicted testing time, design defect failure rate for this probe card structure, design defect failure rate for this probe layout and combinations thereof.

10. The system of claim 1 wherein the optimized phase is the phase during which a probe card performs tests on a customer's semiconductor wafers.

11. The system of claim 10 wherein the current information is selected from a group consisting of: operational, inspection, and repair data, including planarity, alignment, contact resistance, leakage, probe tip diameter, number of touchdowns per probe card, failures per probe card, excess overdrive, scrub length, broken probe rate and combinations thereof.

12. The system of claim 10 wherein the historical data is selected from a group consisting of: operational, inspection, and repair data, including planarity, alignment, contact resistance, leakage, probe tip diameter, number of touchdowns per probe card, failures per probe card, excess overdrive, scrub length, broken probe rate and combinations thereof.

13. The system of claim 10 wherein the metric is selected from a group consisting of: time between probe card failures, predicted probe card failure per wafer, failures per touchdown per probe card, monthly touchdowns, predicted probe card alignment error, radial error per number of probes per number of touchdowns and combinations thereof.

14. The system of claim 1 wherein the optimized phase is the phase during which a probe card is repaired by a supplier.

15. The system of claim 14 wherein the current information is selected from a group consisting of: inspection, repair, and replacement probe card manufacture data, including engineer conducting repair, time to repair, time to manufacture replacement probe card, estimated delivery date and combinations thereof.

16. The system of claim 14 wherein the historical data is selected from a group consisting of: client order backlog, parts supplier data, probe card sophistication, operating efficiency of customer remaining probe cards and combinations thereof.

17. The system of claim 14 wherein the metric is selected from a group consisting of: average repair time per probe card, predicted time to repair probe card of this type, probability replacement is required if probe card is damaged and combinations thereof.

18. The system of claim 1 wherein the probe card customer and supplier store the current information on a storage device that is affixed to the probe card.

19. The probe card of claim 18 wherein the storage device comprises an RFID tag.

20. The system of claim 1 wherein the receiving, calculating, comparing, and communicating functions of said application are automated.
